(19) United States
(12) Patent Application Publication
(10) Pub. No.: US 2018/0366591 A1
(43) Pub. Date: Dec. 20, 2018

(54) THRESHOLD SWITCHING DEVICE

(71) Applicant: Postech Academy-Industry Foundation, Pohang-si (KR)

(72) Inventors: JeongHwan SONG, Pohang-si (KR); HyungSang HWANG, Daegu (KR)

(73) Assignee: Postech Academy-Industry Foundation, Pohang-si (KR)

(21) Appl. No.: 15/687,962

(22) Filed: Aug. 28, 2017

(30) Foreign Application Priority Data
Jun. 14, 2017 (KR) 10-2017-0075082

(51) Int. Cl. H01L 29/861; H01L 29/24; H01L 29/66; H01L 29/45; H01L 45/00

(52) U.S. Cl. CPC H01L 29/8615; H01L 29/24; H01L 29/66969; H01L 29/45; H01L 27/2436; H01L 45/147; H01L 45/146; H01L 45/1273; H01L 45/1233

(57) ABSTRACT

A threshold switching device is provided. The threshold switching device includes a first electrode and a second electrode spaced apart from each other, and a switching layer disposed between the first electrode and the second electrode. The switching layer includes an internal electric field.

### CROSS-REFERENCE TO RELATED APPLICATION

This U.S. non-provisional patent application claims priority under 35 U.S.C. § 119 to Korean Patent Application No. 10-2017-0075082, filed on Jun. 14, 2017, in the Korean Intellectual Property Office, the disclosure of which is hereby incorporated by reference in its entirety.

### BACKGROUND

Embodiments of the inventive concepts relate to a threshold switching device and, more particularly, to a threshold switching device including a switching layer including an internal electric field.

Generally, a memory device includes a plurality of memory elements and selection elements for selecting the memory elements. Various researches have been conducted to provide high-capacity and highly integrated memory devices. In a research, the selection element uses a threshold switching device, not a transistor.

The threshold switching device is a switching device of which a resistance is significantly changed at a specific voltage. When the threshold switching device is used as the selection element of the memory device, a highly integrated memory device may be realized without a complex layout or a complex process.

### SUMMARY

Embodiments of the inventive concepts may provide a threshold switching device having a high operating current and a fast relaxation speed.

In an aspect, a threshold switching device may include a first electrode and a second electrode spaced apart from each other, and a switching layer disposed between the first electrode and the second electrode. The switching layer may include a P-type oxide semiconductor layer and an N-type oxide semiconductor layer.

In some embodiments, the P-type oxide semiconductor layer and the N-type oxide semiconductor layer may be in contact with each other.

In some embodiments, the switching layer may include a depletion region.

In some embodiments, the P-type oxide semiconductor layer may include at least one of nickel oxide, copper oxide, copper-aluminum oxide, zinc-rhodium oxide, or strontium-copper oxide. The N-type oxide semiconductor layer may include at least one of titanium oxide, zinc oxide, tantalum oxide, hafnium oxide, tungsten oxide, aluminum oxide, niobium oxide, zirconium oxide, indium oxide, indium-zinc oxide, gallium-indium-zinc oxide, tin oxide, or indium-tin oxide.

In some embodiments, the second electrode may include at least one of silver or copper.

In some embodiments, the second electrode may further include tellurium (Te).

In some embodiments, the first electrode may include at least one of platinum, tungsten, ruthenium, titanium nitride, or tantalum nitride.

In some embodiments, the threshold switching device may become a low-resistance state when an operating voltage equal to or greater than a threshold voltage is applied between the first electrode and the second electrode, and the threshold switching device may become a high-resistance state when the operating voltage is interrupted.

In some embodiments, a conductive filament connecting the first electrode to the second electrode may be formed in the switching layer when an operating voltage equal to or greater than a threshold voltage is applied between the first electrode and the second electrode, and the conductive filament may be broken when the operating voltage is interrupted.

In an aspect, a threshold switching device may include a first electrode and a second electrode spaced apart from each other, and a switching layer disposed between the first electrode and the second electrode. The switching layer may include a ferroelectric material.

In some embodiments, the switching layer may include an internal electric field formed due to spontaneous polarization of the ferroelectric material.

In some embodiments, the internal electric field may have a direction from the first electrode toward the second electrode or a direction from the second electrode toward the first electrode.

In some embodiments, the switching layer may include at least one of lead zirconate titanate (PZT), strontium bismuth tantalate (SBT), hafnium oxide, or zirconium oxide.

In some embodiments, the threshold switching device may become a low-resistance state when an operating voltage equal to or greater than a threshold voltage is applied between the first electrode and the second electrode, and the threshold switching device may become a high-resistance state when the operating voltage is interrupted.

In an aspect, a threshold switching device may include a first electrode and a second electrode spaced apart from each other, and a switching layer disposed between the first electrode and the second electrode. The switching layer may include an internal electric field.

In some embodiments, the internal electric field may have a direction from the first electrode toward the second electrode.

In some embodiments, the internal electric field may have a direction from the second electrode toward the first electrode.

In some embodiments, the switching layer may include a P-type oxide semiconductor layer and an N-type oxide semiconductor layer, which are in contact with each other.

In some embodiments, a depletion region may be formed around an interface of the P-type oxide semiconductor layer and the N-type oxide semiconductor layer, and the internal electric field may be included in the depletion region.

### BRIEF DESCRIPTION OF THE DRAWINGS

The inventive concepts will become more apparent in view of the attached drawings and accompanying detailed description.

FIGS. 1A and 1B are cross-sectional views illustrating threshold switching devices according to some embodiments of the inventive concepts.

FIGS. 2A to 2C are cross-sectional views illustrating an operation method of a threshold switching device according to some embodiments of the inventive concepts.

FIGS. 3A to 3C are cross-sectional views illustrating an operation method of a threshold switching device according to some embodiments of the inventive concepts.

FIG. 4 is a graph showing a voltage-current characteristic of a threshold switching device according to an experimental example of the inventive concepts.

FIG. 5A is a graph showing a resistance characteristic of a threshold switching device according to a comparative example.

FIG. 5B is a graph showing a resistance characteristic of a threshold switching device according to an experimental example of the inventive concepts.

FIGS. 6A and 6B are cross-sectional views illustrating threshold switching devices according to some embodiments of the inventive concepts.

FIG. 7 is a cross-sectional view illustrating an electronic device according to some embodiments of the inventive concepts.

### DETAILED DESCRIPTION OF THE EMBODIMENTS

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a”, “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present. Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Moreover, exemplary embodiments are described herein with reference to cross-sectional illustrations and/or plane illustrations that are idealized exemplary illustrations. In the drawings, the thicknesses of layers and regions are exaggerated for clarity. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

Hereinafter, embodiments of the inventive concepts will be described with reference to the drawings. The following embodiments of the inventive concepts will be described based on the current understanding of the physical phenomena relative to a threshold switching device. However, embodiments of the inventive concepts are not dependent on a specific physical explanation.

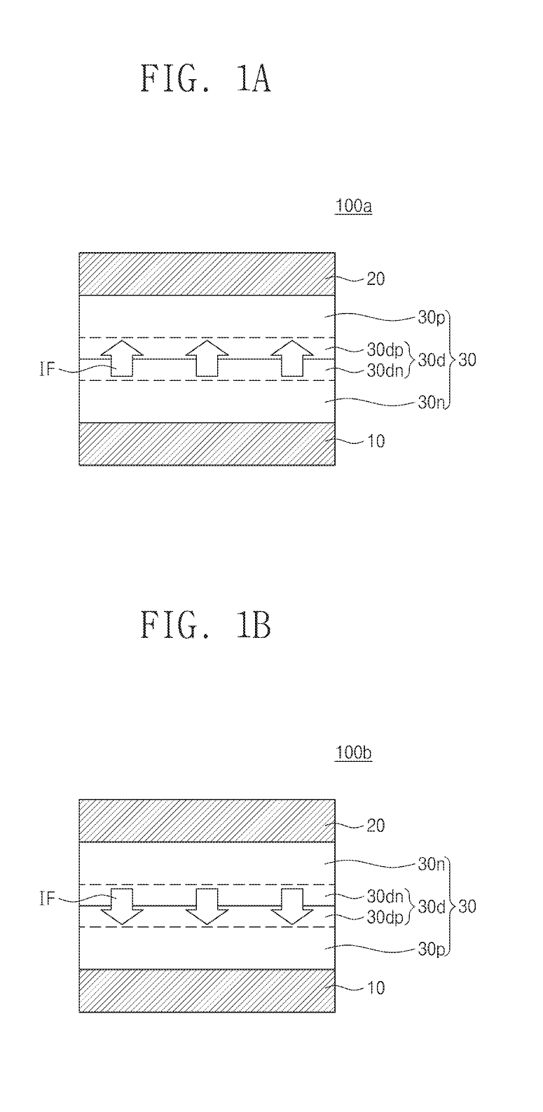

FIGS. 1A and 1B are cross-sectional views illustrating threshold switching devices according to some embodiments of the inventive concepts.

Referring to FIGS. 1A and 1B, a threshold switching device 100a or 100b may include a first electrode 10, a second electrode 20, and a switching layer 30.

The first electrode 10 may include at least one of platinum (Pt), tungsten (W), ruthenium (Ru), titanium nitride (TiN), or tantalum nitride (TaN). The first electrode 10 may have a thickness of, for example, about 10 nm to about 100 nm. The first electrode 10 may be formed using, for example, a chemical vapor deposition (CVD) process or a physical vapor deposition (PVD) process.

The second electrode 20 may be spaced apart from the first electrode 10. The second electrode 20 may include a metal different from the metal included in the first electrode 10. For example, the second electrode 20 may include at least one of silver (Ag) or copper (Cu). The second electrode 20 may have a thickness of, for example, about 10 nm to about 100 nm. The second electrode 20 may be formed using, for example, a CVD)process or a PVD process.

In some embodiments, the second electrode 20 may further include tellurium (Te). For example, the second electrode 20 may include at least one of a silver-tellurium (Ag—Te) alloy or a copper-tellurium (Cu—Te) alloy.

The switching layer 30 may be disposed between the first electrode 10 and the second electrode 20. The switching layer 30 may include an oxide semiconductor. In more detail, the switching layer 30 may include a P-type oxide semiconductor layer 30p and an N-type oxide semiconductor layer 30n. For example, the P-type oxide semiconductor layer 30p may include at least one of nickel oxide, copper oxide, copper-aluminum oxide, zinc-rhodium oxide, or strontium-copper oxide. For example, the N-type oxide semiconductor layer 30n may include at least one of titanium oxide, zinc oxide, tantalum oxide, hafnium oxide, tungsten oxide, aluminum oxide, niobium oxide, zirconium oxide, indium oxide, indium-zinc oxide, gallium-indium-zinc oxide, tin oxide, or indium-tin oxide. Each of the P-type oxide semiconductor layer 30p and the N-type oxide semiconductor layer 30n may have a thickness of, for example, 1 nm to 50 nm. The switching layer 30 may be formed using, for example, a CVD process or a PVD process.

The P-type oxide semiconductor layer 30p and the N-type oxide semiconductor layer 30n may be in contact with each other. In other words, the P-type oxide semiconductor layer 30p and the N-type oxide semiconductor layer 30n may form a PN junction. Thus, a depletion region 30d may be formed in the switching layer 30. In more detail, the depletion region 30d may be formed around an interface of the P-type oxide semiconductor layer 30p and the N-type oxide semiconductor layer 30n.

The depletion region 30d may include a first depletion region 30dp formed in the P-type oxide semiconductor layer 30p and a second depletion region 30dn formed in the N-type oxide semiconductor layer 30n. The first depletion region 30dp may include negative ions, and the second depletion region 30dn may include positive ions. This may be because electrons of the second depletion region 30dn are diffused into the first depletion region 30dp when the PN junction is formed.

The depletion region 30d may include an internal electric field IF formed therein. The internal electric field IF may be formed due to the negative ions of the first depletion region 30dp and the positive ions of the second depletion region 30dn. Thus, the internal electric field IF may have a direction from the second depletion region 30dn toward the first depletion region 30dp.

In some embodiments, as illustrated in FIG. 1A, the P-type oxide semiconductor layer 30p may be disposed adjacent to the second electrode 20 and the N-type oxide semiconductor layer 30n may be disposed adjacent to the first electrode 10. In other words, the P-type oxide semiconductor layer 30p may be disposed between the N-type oxide semiconductor layer 30n and the second electrode 20. In these embodiments, the internal electric field IF may have a direction from the first electrode 10 toward the second electrode 20.

In other embodiments, as illustrated in FIG. 1B, the P-type oxide semiconductor layer 30p may be disposed adjacent to the first electrode 10 and the N-type oxide semiconductor layer 30n may be disposed adjacent to the second electrode 20. In other words, the P-type oxide semiconductor layer 30p may be disposed between the first electrode 10 and the N-type oxide semiconductor layer 30n. In these embodiments, the internal electric field IF may have a direction from the second electrode 20 toward the first electrode 10.

When an operating voltage equal to or greater than a threshold voltage is applied between the first electrode 10 and the second electrode 20, a conductive filament (not shown) connecting the first and second electrodes 10 and 20 to each other may be formed in the switching layer 30. Thus, the threshold switching device 100a or 100b may become a turn-on state (or a low-resistance state). For example, the operating voltage may be applied to generate an external electric field having a direction from the second electrode 20 toward the first electrode 10 in the switching layer 30. Ions of the metal (e.g., Ag⁺ or Cu⁺) included in the second electrode 20 may be moved toward the first electrode 10 by the external electric field, and these metal ions may be linked with each other to form the conductive filament connecting the first and second electrodes 10 and 20.

When a voltage less than the threshold voltage is applied between the first electrode 10 and the second electrode 20, the conductive filament may be broken. For example, when the operating voltage is interrupted, the conductive filament may be broken. Thus, the threshold switching device 100a or 100b may become a turn-off state (or a high-resistance state).

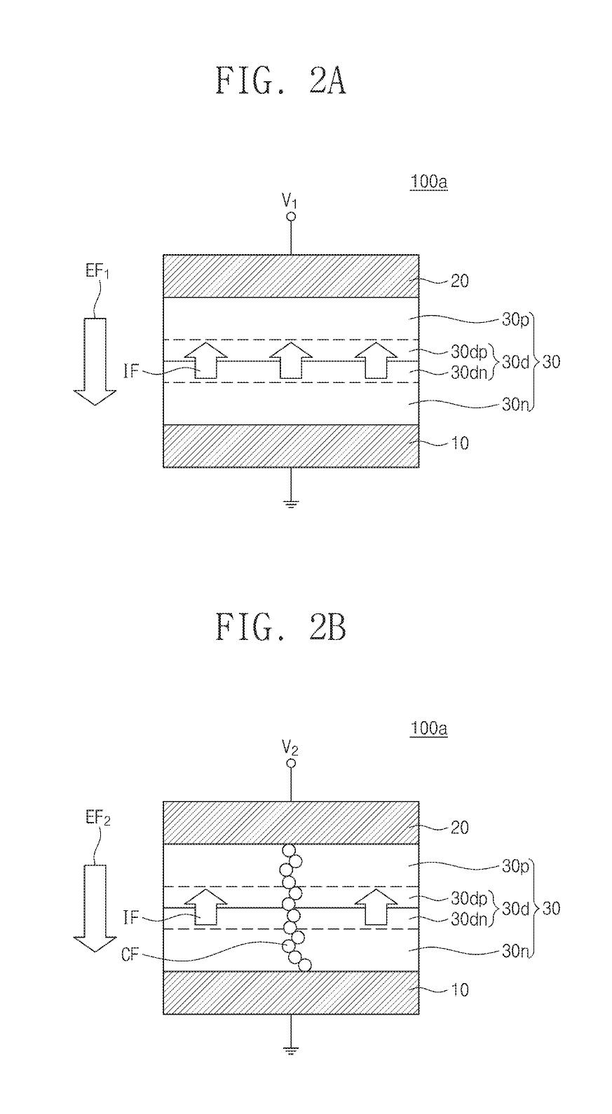

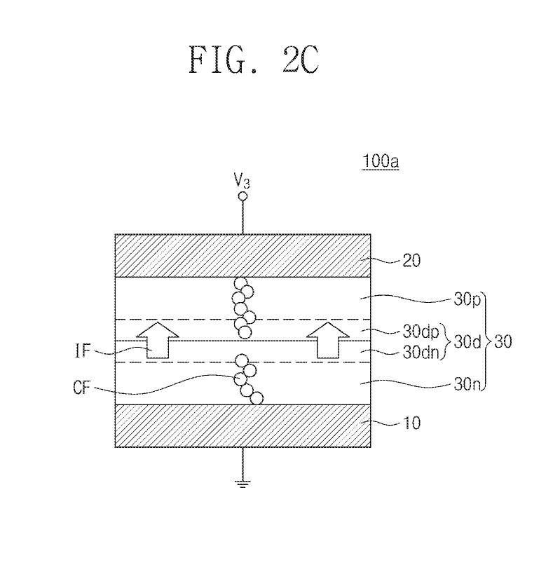

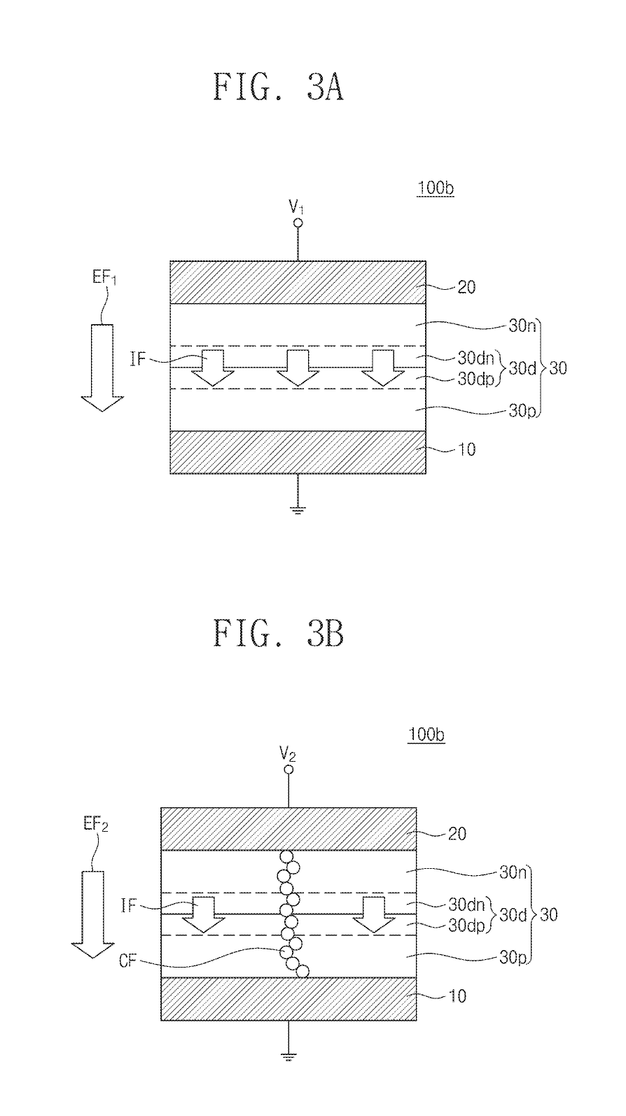

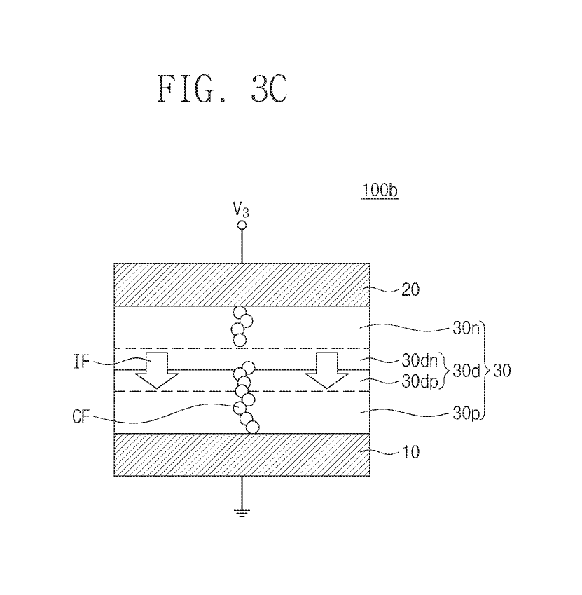

The internal electric field IF may assist the threshold switching device 100a or 100b to be switched from the turn-on state to the turn-off state. In other words, the internal electric field IF may accelerate the breakage (or decomposition) of the conductive filament. Thus, the threshold switching device 100a or 100b according to some embodiments of the inventive concepts may have a higher operating current and a faster relaxation speed. Here, the operating current means a current that flows through the threshold switching device 100a or 100b in the turn-on state, and the relaxation speed means a speed at which the threshold switching device 100a or 100b is switched from the turn-on state to the turn-off state. These effects of the inventive concepts will be described later in more detail with reference to FIGS. 2A to 2C or 3A to 3C.

In some embodiments, the threshold switching device 100a or 100b may be used as a selection element of a memory device. For example, the threshold switching device 100a or 100b may be used as a selection element of a variable resistance memory device having a cross-point structure. In this case, the threshold switching device 100a or 100band a variable resistance element may be connected in series between a pair of conductive lines extending in directions intersecting each other.

FIGS. 2A to 2C are cross-sectional views illustrating an operation method of a threshold switching device according to some embodiments of the inventive concepts. In more detail, FIGS. 2A to 2C are cross-sectional views illustrating an operation method of the threshold switching device 100a described with reference to FIG. 1A. Hereinafter, the same components as described with reference to FIG. 1A will be indicated by the same reference numerals or the same reference designators, and the duplicated descriptions thereto will be omitted or mentioned briefly for the purpose of ease and convenience in explanation.

Referring to FIG. 2A, a first voltage V₁ lower than the threshold voltage may be applied between the first electrode 10 and the second electrode 20. For example, the first electrode 10 may be grounded, and the first voltage V₁ that is a positive voltage may be applied to the second electrode 20.

A first external electric field EF₁ may be formed between the first electrode 10 and the second electrode 20 by the first voltage V₁. The first external electric field EF₁ may have a direction from the second electrode 20 toward the first electrode 10. The first external electric field EF₁ may not be large enough to form the conductive filament in the switching layer 30, and thus the conductive filament may not be formed in the switching layer 30. As a result, the threshold switching device 100a may be in the turn-off state.

Referring to FIG. 2B, a second voltage V₂ higher than the threshold voltage may be applied between the first electrode 10 and the second electrode 20. For example, the first electrode 10 may be grounded, and the second voltage V₂ that is a positive voltage may be applied to the second electrode 20.

A second external electric field EF₂ may be formed between the first electrode 10 and the second electrode 20 by the second voltage V₂. The second external electric field EF₂ may have a direction from the second electrode 20 toward the first electrode 10. A magnitude of the second external electric field EF₂ may be greater than a magnitude of the internal electric field IF.

A conductive filament CF connecting the first and second electrodes 10 and 20 may be formed in the switching layer 30 by the second external electric field EF₂. For example, the metal ions (e.g., Ag⁺ or Cu³⁰ ) included in the second electrode 20 may be moved toward the first electrode 10 by the second external electric field EF₂, and these metal ions may be linked with each other to form the conductive filament CF connecting the first and second electrodes 10 and 20.

Due to the formation of the conductive filament CF, a resistance of the threshold switching device 100a may be rapidly reduced, and a current flowing through the threshold switching device 100a may be rapidly increased. In other words, the threshold switching device 100a may be switched to the turn-on state.

Referring to FIG. 2C, a third voltage V₃ lower than the threshold voltage may be applied between the first electrode 10 and the second electrode 20. For example, the third voltage V₃ may be 0 (zero). In other words, the second voltage V₂ may be interrupted.

When the third voltage V₃ is applied, the conductive filament CF may be spontaneously decomposed. Thus, the conductive filament CF connecting the first and second electrodes 10 and 20 may be broken.

Since the conductive filament CF connecting the first and second electrodes 10 and 20 is broken, the resistance of the threshold switching device 100a may be rapidly increased and the current flowing through the threshold switching device 100a may be rapidly reduced. In other words, the threshold switching device 100a may be switched to the turn-off state.

The internal electric field IF formed in the depletion region 30d may accelerate the spontaneous decomposition of the conductive filament CF. For example, the internal electric field IF may apply electric force to the metal ions existing in the depletion region 30d, and thus movement of the metal ions in the depletion region 30d may be accelerated. Since the internal electric field IF has the direction from the first electrode 10 toward the second electrode 20 in the threshold switching device 100a, the internal electric field IF may accelerate the movement of the metal ions in the depletion region 30d toward the second electrode 20.

FIGS. 3A to 3C are cross-sectional views illustrating an operation method of a threshold switching device according to some embodiments of the inventive concepts. In more detail, FIGS. 3A to 3C are cross-sectional views illustrating an operation method of the threshold switching device 100bdescribed with reference to FIG. 1B. Hereinafter, the same components as described with reference to FIG. 1B will be indicated by the same reference numerals or the same reference designators, and the duplicated descriptions thereto will be omitted or mentioned briefly for the purpose of ease and convenience in explanation.

Referring to FIG. 3A, a first voltage V₁ lower than the threshold voltage may be applied between the first electrode 10 and the second electrode 20. For example, the first electrode 10 may be grounded, and the first voltage V₁ that is a positive voltage may be applied to the second electrode 20.

A first external electric field EF₁ may be formed between the first electrode 10 and the second electrode 20 by the first voltage V₁. The first external electric field EF₁ may have a direction from the second electrode 20 toward the first electrode 10.

As described with reference to FIG. 2A, the conductive filament may not formed in the switching layer 30. Thus, the threshold switching device 100b may be in the turn-off state.

Referring to FIG. 3B, a second voltage V₂ higher than the threshold voltage may be applied between the first electrode 10 and the second electrode 20. For example, the first electrode 10 may be grounded, and the second voltage V₂ that is a positive voltage may be applied to the second electrode 20.

A second external electric field EF₂ may be formed between the first electrode 10 and the second electrode 20 by the second voltage V₂. The second external electric field EF₂ may have a direction from the second electrode 20 toward the first electrode 10. Since the internal electric field IF has the direction from the second electrode 20 toward the first electrode 10 in the threshold switching device 100b, the direction of the second external electric field EF₂ may be substantially the same as the direction of the internal electric field IF. A magnitude of the second external electric field EF₂ may be greater than a magnitude of the internal electric field IF.

As described with reference to FIG. 2B, a conductive filament CF connecting the first and second electrodes 10 and 20 may be formed in the switching layer 30 by the second external electric field EF₂. Since the internal electric field IF has the direction from the second electrode 20 toward the first electrode 10, the internal electric field IF may assist the formation of the conductive filament CF.

Due to the formation of the conductive filament CF, a resistance of the threshold switching device 100b may be rapidly reduced, and a current flowing through the threshold switching device 100b may be rapidly increased. In other words, the threshold switching device 100b may be switched to the turn-on state.

Referring to FIG. 3C, a third voltage V₃ lower than the threshold voltage may be applied between the first electrode 10 and the second electrode 20. For example, the third voltage V₃ may be 0 (zero). In other words, the second voltage V₂ may be interrupted.

As described with reference to FIG. 2C, when the third voltage V₃ is applied, the conductive filament CF may be spontaneously decomposed. Thus, the conductive filament CF connecting the first and second electrodes 10 and 20 may be broken, and the threshold switching device 100b may be switched to the turn-off state.

The internal electric field IF formed in the depletion region 30d may accelerate the spontaneous decomposition of the conductive filament CF. For example, the internal electric field IF may apply electric force to the metal ions existing in the depletion region 30d, and thus movement of the metal ions in the depletion region 30d may be accelerated. Since the internal electric field IF has the direction from the second electrode 20 toward the first electrode 10 in the threshold switching device 100b, the internal electric field IF may accelerate the movement of the metal ions in the depletion region 30d toward the first electrode 10.

In a general threshold switching device, if a thick conductive filament is formed, the conductive filament may not be spontaneously decomposed even though an operating voltage is interrupted. If the conductive filament is not spontaneously decomposed even through the operating voltage is interrupted, a device may function as a non-volatile memory element, not a threshold switching device. Thus, it is difficult for the general threshold switching device to have a high operating current.

According to embodiments of the inventive concepts, even though the conductive filament CF is thickly formed, the conductive filament CF may be spontaneously decomposed due to the internal electric field IF. Thus, according to embodiments of the inventive concepts, the threshold switching device 100a or 100b may have a higher operating current.

In addition, according to embodiments of the inventive concepts, the conductive filament CF may be quickly broken (or decomposed) due to the internal electric field IF when the operating voltage (i.e., the second voltage V₂) is interrupted. Thus, according to embodiments of the inventive concepts, the threshold switching device 100a or 100b may have a faster relaxation speed.

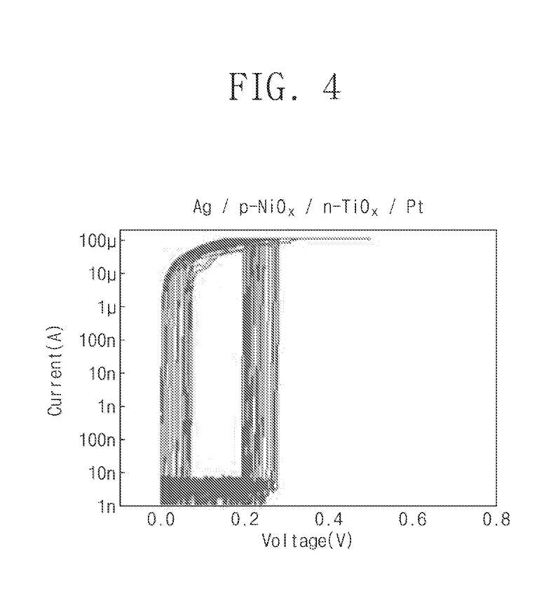

FIG. 4 is a graph showing a voltage-current characteristic of a threshold switching device according to an experimental example of the inventive concepts.

A threshold switching device according to an experimental example of the inventive concepts was formed to have the structure of the threshold switching device 100a described with reference to FIG. 1A. In more detail, the threshold switching device according to the experimental example was formed to include a first electrode, an N-type oxide semiconductor layer, a P-type oxide semiconductor layer, and a second electrode, which were sequentially stacked. The first electrode was formed of platinum, and the N-type oxide semiconductor layer was formed of titanium oxide. The P-type oxide semiconductor layer was formed of nickel oxide, and the second electrode was formed of silver. A thickness of the N-type oxide semiconductor layer was about 5 nm, and a thickness of the P-type oxide semiconductor layer was about 15 nm.

Referring to FIG. 4, the threshold switching device according to the experimental example of the inventive concepts operates as a threshold switching device when an operating current is about 100 μA.

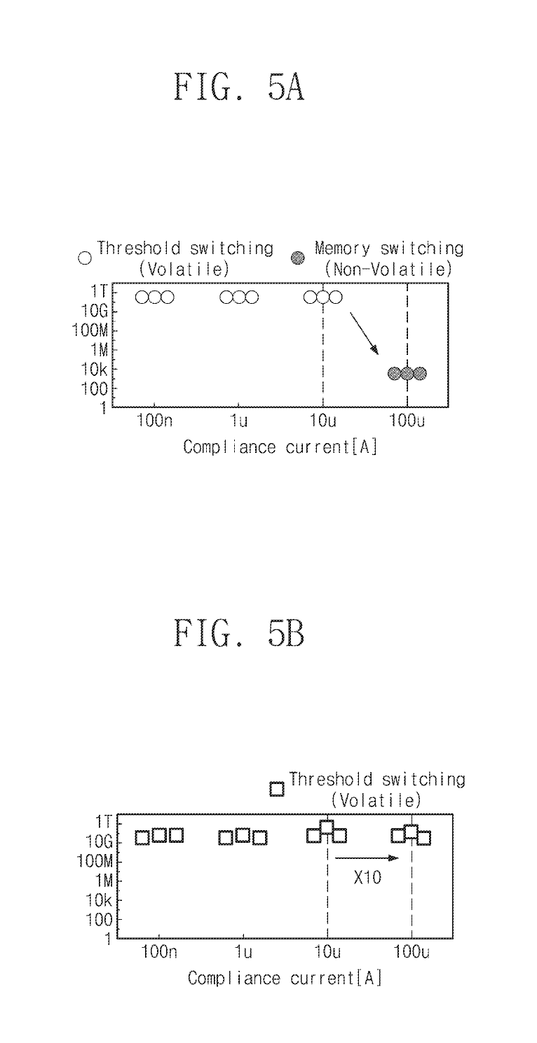

FIG. 5A is a graph showing a resistance characteristic of a threshold switching device according to a comparative example.

A threshold switching device according to a comparative example was formed to include a first electrode, a switching layer, and a second electrode, which were sequentially stacked. The first electrode was formed of platinum, the switching layer was formed of titanium oxide, and the second electrode was formed of silver. A thickness of the switching layer was about 5 nm.

Operating voltages were applied to allow currents of about 100 nA, about 1 μA, about 10 μA, and about 100 μA to flow through the threshold switching device according to the comparative example, respectively, and each of the operating voltages was interrupted after each of the operating voltages was applied. After each of the operating voltages was interrupted, a voltage of about 0.1V lower than a threshold voltage was applied again to the threshold switching device according to the comparative example to measure a resistance of the threshold switching device.

Referring to FIG. 5A, the threshold switching device according to the comparative example still has a high resistance after each of the currents of about 100 nA, about 1 μA, and about 10 μA flows. This means that a conductive filament formed by the operating voltage is spontaneously broken when the operating voltage is interrupted after each of the currents of about 100 nA, about 1 μA, and about 10 μA flows through the threshold switching device according to the comparative example.

In contrast, a resistance of the threshold switching device according to the comparative example is significantly reduced after the current of about 100 μA flows. This means that a conductive filament formed by the operating voltage is not spontaneously broken even though the operating voltage is interrupted after the current of about 100 μA flows through the threshold switching device according to the comparative example.

As a result, the threshold switching device according to the comparative example functions as a threshold switching device by the operating current of about 100 nA, about 1 μA, or about 10 μA but functions as a non-volatile memory element by the operating current of about 100 μA.

FIG. 5B is a graph showing a resistance characteristic of a threshold switching device according to an experimental example of the inventive concepts.

A threshold switching device according to the present experimental example of the inventive concepts was the same as the threshold switching device according to the experimental example of FIG. 4.

Operating voltages were applied to allow currents of about 100 nA, about 1 μA, about 10 μA, and about 100 μA to flow through the threshold switching device according to the experimental example of the inventive concepts, respectively, and each of the operating voltages was interrupted after each of the operating voltages was applied. After each of the operating voltages was interrupted, a voltage of about 0.1V lower than a threshold voltage was applied again to the threshold switching device according to the experimental example of the inventive concepts to measure a resistance of the threshold switching device.

Referring to FIG. 5B, the threshold switching device according to the experimental example of the inventive concepts still has a high resistance after each of the currents of about 100 nA, about 1 μA, about 10 μA, and about 100 μA flows. This means that a conductive filament formed by the operating voltage is spontaneously broken when the operating voltage is interrupted after each of the currents of about 100 nA, about 1 μA, about 10 μA, and about 100 μA flows through the threshold switching device according to the experimental example of the inventive concepts.

In other words, unlike the threshold switching device according to the comparative example, the threshold switching device according to the experimental example of the inventive concepts also functions as a threshold switching device when the operating current of about 100 μA flows.

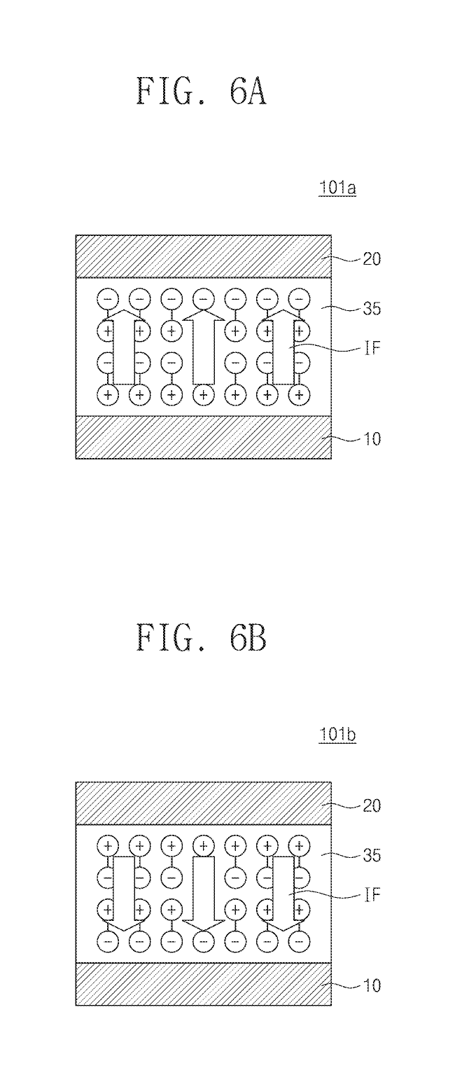

FIGS. 6A and 6B are cross-sectional views illustrating threshold switching devices according to some embodiments of the inventive concepts.

Referring to FIGS. 6A and 6B, a threshold switching device 101a or 101b may include a first electrode 10, a second electrode 20, and a switching layer 35.

The first electrode 10 and the second electrode 20 may be substantially the same as described with reference to FIGS. 1A and 1B. For the purpose of ease and convenience in explanation, the duplicated descriptions to the first and second electrodes 10 and 20 will be omitted or mentioned briefly.

The switching layer 35 may be interposed between the first electrode 10 and the second electrode 20. The switching layer 35 may include a ferroelectric material. For example, the switching layer 35 may include at least one of lead zirconate titanate (PZT), strontium bismuth tantalate (SBT), hafnium oxide, or zirconium oxide. In the case in which the switching layer 35 includes hafnium oxide or zirconium oxide, the switching layer 35 may be doped with impurities. For example, the impurities may include at least one of silicon (Si), aluminum (Al), germanium (Ge), magnesium (Mg), calcium (Ca), strontium (Sr), niobium (Nb), yttrium (Y), barium (Ba), or titanium (Ti).

The switching layer 35 may include an internal electric field IF. The internal electric field IF may be formed due to spontaneous polarization of the ferroelectric material. For example, when an external electric field of which a magnitude is equal to or greater than a specific value is applied to the switching layer 35, the ferroelectric material may have the spontaneous polarization, and the internal electric field IF may be formed in the switching layer 35 thereby. The spontaneous polarization and the internal electric field IF may be maintained even though the external electric field is removed.

In some embodiments, the internal electric field IF may have a direction from the first electrode 10 toward the second electrode 20, as illustrated in FIG. 6A. For example, an external electric field may be applied to the switching layer 35 in a direction from the second electrode 20 toward the first electrode 10. Thus, the ferroelectric material may have the spontaneous polarization in the direction from the first electrode 10 toward the second electrode 20, and the internal electric field IF having the direction from the first electrode 10 toward the second electrode 20 may be formed in the switching layer 35 by the spontaneous polarization. The external electric field may be applied to the switching layer 35 through the first and second electrodes 10 and 20. The spontaneous polarization and the internal electric field IF may be maintained even if the external electric field is removed.

In other embodiments, the internal electric field IF may have a direction from the second electrode 20 toward the first electrode 10, as illustrated in FIG. 6B. For example, an external electric field may be applied to the switching layer 35 in a direction from the first electrode 10 toward the second electrode 20. Thus, the ferroelectric material may have the spontaneous polarization in the direction from the second electrode 20 toward the first electrode 10, and the internal electric field IF having the direction from the second electrode 20 toward the first electrode 10 may be formed in the switching layer 35 by the spontaneous polarization. The external electric field may be applied to the switching layer 35 through the first and second electrodes 10 and 20. The spontaneous polarization and the internal electric field IF may be maintained even though the external electric field is removed.

When an operating voltage equal to or greater than a threshold voltage is applied between the first electrode 10 and the second electrode 20, a conductive filament (not shown) connecting the first and second electrodes 10 and 20 may be formed in the switching layer 35. Thus, the threshold switching device 101a or 101b may become a turn-on state (or a low-resistance state).

When a voltage less than the threshold voltage is applied between the first electrode 10 and the second electrode 20, the conductive filament may be broken. For example, when the operating voltage is interrupted, the conductive filament may be broken. Thus, the threshold switching device 100a or 100b may become a turn-off state (or a high-resistance state).

The internal electric field IF may assist the threshold switching device 101a or 101b to be switched from the turn-on state to the turn-off state. In other words, the internal electric field IF may accelerate the breakage (or decomposition) of the conductive filament. Thus, the threshold switching device 101a or 101b according to some embodiments of the inventive concepts may have a higher operating current and a faster relaxation speed. Here, the operating current means a current that flows through the threshold switching device 101a or 101b in the turn-on state, and the relaxation speed means a speed at which the threshold switching device 101a or 101b is switched from the turn-on state to the turn-off state.

These effects of the inventive concepts may be substantially the same as described with reference to FIGS. 2A to 2C or 3A to 3C. In some embodiments, when the internal electric field IF has the direction from the first electrode 10 toward the second electrode 20 as illustrated in FIG. 6A, an operation of the threshold switching device 101a may be substantially the same as the operation of the threshold switching device 100a described with reference to FIGS. 2A to 2C. In other embodiments, when the internal electric field IF has the direction from the second electrode 20 toward the first electrode 10 as illustrated in FIG. 6B, an operation of the threshold switching device 101b may be substantially the same as the operation of the threshold switching device 100b described with reference to FIGS. 3A to 3C.

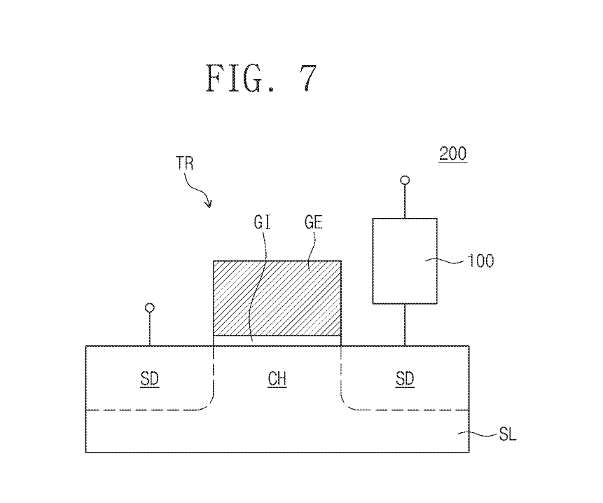

FIG. 7 is a cross-sectional view illustrating an electronic device according to some embodiments of the inventive concepts.

Referring to FIG. 7, an electronic device 200 may include a transistor TR and at least one threshold switching device 100. The threshold switching device 100 may be one of the threshold switching devices 100a and 100b described with reference to FIGS. 1A and 1B or one of the threshold switching devices 101a and 101b described with reference to FIGS. 6A and 6B.

The transistor TR may include a semiconductor layer SL, a gate electrode GE, a gate insulating layer GI, and a pair of source/drain regions SD.

The semiconductor layer SL may include a semiconductor material having a first conductivity type. For example, the semiconductor layer SL may include silicon, germanium, or silicon-germanium.

The gate electrode GE may be disposed on the semiconductor layer SL. The gate electrode GE may include a conductive material. For example, the gate electrode GE may include a semiconductor doped with dopants (e.g., doped silicon, doped germanium, or doped silicon-germanium), a metal (e.g., titanium, tantalum, or tungsten), and/or a conductive metal nitride (e.g., titanium nitride or tantalum nitride).

The gate insulating layer GI may be disposed between the semiconductor layer SL and the gate electrode GE. The gate insulating layer GI may include an insulating material. For example, the gate insulating layer GI may include silicon oxide, silicon nitride, silicon oxynitride, and/or a metal oxide.

The pair of source/drain regions SD may be disposed in the semiconductor layer SL at both sides of the gate electrode GE, respectively. The source/drain regions SD may have a second conductivity type different from the first conductivity type. The semiconductor layer SL between the source/drain regions SD may be defined as a channel region CH.

In some embodiments, the threshold switching device 100 may be electrically connected to one of the source/drain regions SD, as illustrated in FIG. 7. In more detail, a first electrode or a second electrode of the threshold switching device 100 may be electrically connected to one of the source/drain regions SD.

In other embodiments, a pair of the threshold switching devices 100 may be provided, unlike FIG. 7. In these embodiments, the threshold switching devices 100 may be electrically connected to the source/drain regions SD, respectively.

At least one threshold switching device 100 may be electrically connected to at least one of the source/drain regions SD of the transistor TR, and thus the electronic device 200 may be realized to have a gradient equal to or less than a sharp threshold voltage and a high on/off current ratio.

According to embodiments of the inventive concepts, even though the conductive filament is thick, the conductive filament may be spontaneously decomposed by the internal electric field. Thus, the threshold switching device may have a higher operating current.

According to embodiments of the inventive concepts, the conductive filament may be quickly broken by the internal electric field when the operating voltage is interrupted. Thus, the threshold switching device may have a faster relaxation speed.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

1. A threshold switching device comprising:
a first electrode and a second electrode spaced apart from each other; and
a switching layer disposed between the first electrode and the second electrode,
wherein the switching layer comprises: a P-type oxide semiconductor layer and an N-type oxide semiconductor layer.

2. The threshold switching device of claim 1, wherein the P-type oxide semiconductor layer and the N-type oxide semiconductor layer are in contact with each other.

3. The threshold switching device of claim 1, wherein the switching layer includes a depletion region.

4. The threshold switching device of claim 1, wherein the P-type oxide semiconductor layer includes at least one of nickel oxide, copper oxide, copper-aluminum oxide, zinc-rhodium oxide, or strontium-copper oxide, and
wherein the N-type oxide semiconductor layer includes at least one of titanium oxide, zinc oxide, tantalum oxide, hafnium oxide, tungsten oxide, aluminum oxide, niobium oxide, zirconium oxide, indium oxide, indium-zinc oxide, gallium-indium-zinc oxide, tin oxide, or indium-tin oxide.

5. The threshold switching device of claim 1, wherein the second electrode includes at least one of silver or copper.

6. The threshold switching device of claim 5, wherein the second electrode further includes tellurium (Te).

7. The threshold switching device of claim 5, wherein the first electrode includes at least one of platinum, tungsten, ruthenium, titanium nitride, or tantalum nitride.

8. The threshold switching device of claim 1, wherein the threshold switching device becomes a low-resistance state when an operating voltage equal to or greater than a threshold voltage is applied between the first electrode and the second electrode, and
wherein the threshold switching device becomes a high-resistance state when the operating voltage is interrupted.

9. The threshold switching device of claim 1, wherein a conductive filament connecting the first electrode to the second electrode is formed in the switching layer when an operating voltage equal to or greater than a threshold voltage is applied between the first electrode and the second electrode, and
wherein the conductive filament is broken when the operating voltage is interrupted.

10. A threshold switching device comprising:
a first electrode and a second electrode spaced apart from each other; and
a switching layer disposed between the first electrode and the second electrode,
wherein the switching layer includes a ferroelectric material.

11. The threshold switching device of claim 10, wherein the switching layer includes an internal electric field formed due to spontaneous polarization of the ferroelectric material.

12. The threshold switching device of claim 11, wherein the internal electric field has a direction from the first electrode toward the second electrode or a direction from the second electrode toward the first electrode.

13. The threshold switching device of claim 10, wherein the switching layer includes at least one of lead zirconate titanate (PZT), strontium bismuth tantalate (SBT), hafnium oxide, or zirconium oxide.

14. The threshold switching device of claim 10, wherein the threshold switching device becomes a low-resistance state when an operating voltage equal to or greater than a threshold voltage is applied between the first electrode and the second electrode, and
wherein the threshold switching device becomes a high-resistance state when the operating voltage is interrupted.

15. A threshold switching device comprising:
a first electrode and a second electrode spaced apart from each other; and
a switching layer disposed between the first electrode and the second electrode,
wherein the switching layer includes an internal electric field.

16. The threshold switching device of claim 15, wherein the internal electric field has a direction from the first electrode toward the second electrode.

17. The threshold switching device of claim 15, wherein the internal electric field has a direction from the second electrode toward the first electrode.

18. The threshold switching device of claim 15, wherein the switching layer comprises: a P-type oxide semiconductor layer and an N-type oxide semiconductor layer, which are in contact with each other.

19. The threshold switching device of claim 18, wherein a depletion region is formed around an interface of the P-type oxide semiconductor layer and the N-type oxide semiconductor layer, and
wherein the internal electric field is included in the depletion region.

20. The threshold switching device of claim 15, wherein the switching layer includes a ferroelectric material.
